(19) United States
(12) Patent Application Publication
(10) Pub. No.: US 2026/0247651 A1
(43) Pub. Date: Aug. 20, 2026

(54) SEMICONDUCTOR DEVICE

(71) Applicant: Kabushiki Kaisha Toshiba, Kawasaki-shi (JP)

(72) Inventors: Peitsen Wu, Kawasaki Kanagawa (JP); Yosuke Kajiwara, Yokohama Kanagawa (JP)

(21) Appl. No.: 19/538,729

(22) Filed: Feb. 12, 2026

(30) Foreign Application Priority Data
Feb. 18, 2025 (JP) 2025-024410

(51) Int. Cl. H10D 30/47; H10D 62/824; H10D 64/27

(52) U.S. Cl. CPC H10D 30/476; H10D 62/824; H10D 64/513

(57) ABSTRACT

According to one embodiment, there is provided a semiconductor device which includes first to third electrodes, a semiconductor member, and an insulating member. The semiconductor member includes a first semiconductor region including Alₓ₁Ga₁₋ₓ₁N (0≤x1<1), a second semiconductor region including Alₓ₂Ga₁₋ₓ₂N (0<x2<1, x1<x2), a first compound region including and Alₓ₃Ga₁₋ₓ₃N (0<x3≤1, x2<x3), and an intermediate compound region including a first intermediate compound portion. The intermediate compound region includes at least one selected from the group consisting of a first material, a second material, and a third material. The first material includes Alₓ₄Ga₁₋ₓ₄N (0≤x4<1, x4<x3). The second material includes In_{y1}Al_{y2}Ga_{1-y1-y2}N (0<y1≤1, 0≤y2<1, y1+y2≤1). The third material includes ZnO.

### CROSS-REFERENCE TO RELATED APPLICATION(S)

This application is based upon and claims the benefit of priority from Japanese Patent Application No. 2025-024410, filed Feb. 18, 2025, the entire contents of which are incorporated herein by reference.

### FIELD

Embodiments of the present invention relate to a semiconductor device.

### BACKGROUND

For example, it is desirable to improve characteristics of a semiconductor device such as a transistor.

### BRIEF DESCRIPTION OF THE DRAWINGS

FIG. 1 is a schematic cross-sectional view illustrating a semiconductor device according to a first embodiment.

FIG. 2 is a graph illustrating characteristics of the semiconductor device according to the first embodiment.

FIG. 3 is a graph illustrating characteristics of the semiconductor device according to the first embodiment.

FIG. 4 is a graph illustrating characteristics of the semiconductor device according to the first embodiment.

FIG. 5 is a graph illustrating characteristics of the semiconductor device according to the first embodiment.

FIG. 6 is a schematic cross-sectional view illustrating a semiconductor device according to the first embodiment.

### DETAILED DESCRIPTION

In general, according to one embodiment, there is provided a semiconductor device which includes a first electrode, a second electrode, a third electrode, a semiconductor member, and a first insulating member. A direction from the first electrode toward the second electrode is aligned with a first direction. The third electrode includes a first electrode portion. A third electrode position of the first electrode portion in the first direction is between a first electrode position of the first electrode in the first direction and a second electrode position of the second electrode in the first direction. The semiconductor member includes a first semiconductor region including Alₓ₁Ga₁₋ₓ₁N (0≤x1<1), a second semiconductor region including Alₓ₂Ga₁₋ₓ₂N (0<x2<1, x1<x2), a first compound region including to Alₓ₃Ga₁₋ₓ₃N (0<x3≤1, x2<x3), and an intermediate compound region including a first intermediate compound portion. The first semiconductor region includes a first partial region, a second partial region, a third partial region, a fourth partial region, and a fifth partial region. A direction from the first partial region toward the first electrode is aligned with a second direction crossing the first direction. A direction from the second partial region toward the second electrode is aligned with the second direction. A direction from the third partial region toward the first electrode portion is aligned with the second direction. A fourth partial region position of the fourth partial region in the first direction is between a first partial region position of the first partial region in the first direction and a third partial region position of the third partial region in the first direction. A fifth partial region position of the fifth partial region in the first direction is between the third partial region position and a second partial region position of the second partial region in the first direction. The second semiconductor region includes a first semiconductor portion and a second semiconductor portion. A direction from the fourth partial region toward the first semiconductor portion is aligned with the second direction. A direction from the fifth partial region toward the second semiconductor portion is aligned with the second direction. At least a portion of the first electrode portion is between the first semiconductor portion and the second semiconductor portion in the first direction. The first compound region includes a first region, a second region, and a third region. The first region is between the first semiconductor portion and the first electrode portion in the first direction. The second region is between the first electrode portion and the second semiconductor portion in the first direction. The third region is between the third partial region and the first electrode portion in the second direction. The first intermediate compound portion is between the first electrode portion and the second region in the first direction. The first insulating member includes a first insulating region, a second insulating region, and a third insulating region. The first insulating region is between the first region and the first electrode portion in the first direction. The second insulating region is between the first electrode portion and the first intermediate compound portion in the first direction. The third insulating region is between the third region and the first electrode portion in the second direction. The third region contacts the third partial region and the third insulating region. The intermediate compound region includes at least one selected from the group consisting of a first material, a second material, and a third material. The first material includes Alₓ₄Ga₁₋ₓ₄N (0≤x4<1, x4<x3). The second material includes In_{y1}Al_{y2}Ga_{1-y1-y2}N (0<y1≤1, 0≤y2<1, y1+y2≤1). The third material includes ZnO.

Hereinafter, embodiments of the present invention will be described with reference to the drawings. The drawings are schematic or conceptual, and the relationship between the thickness and width of each portion, the ratio of the sizes between portions, and the like are not necessarily the same as the actual ones. Even when the same portion is illustrated, the dimensions and ratios may be illustrated differently depending on the drawings. In the specification and the drawings, the same reference numerals are given to the same elements as those described above with reference to the drawings that have already been referred to, and detailed description thereof will be omitted as appropriate.

### First Embodiment

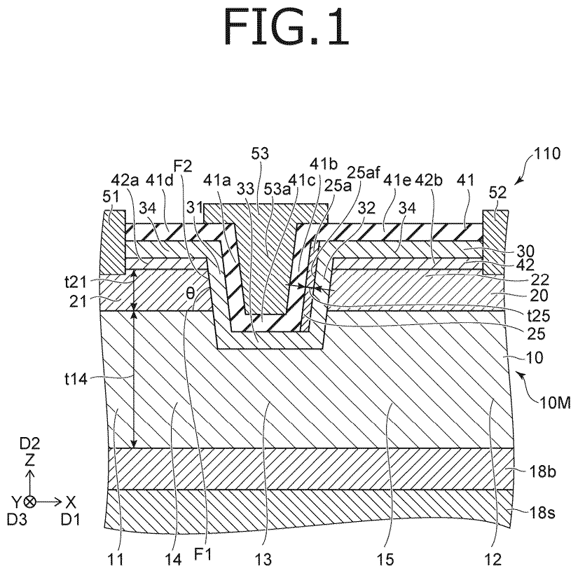

FIG. 1 is a schematic cross-sectional view illustrating a semiconductor device according to a first embodiment. As shown in FIG. 1, the semiconductor device 110 according to the embodiment includes first electrodes 51, second electrodes 52, third electrodes 53, a semiconductor member 10M, and a first insulating member 41.

The direction from the first electrode 51 toward the second electrode 52 is aligned with the first direction D1. The first direction D1 is taken as an X-axis direction. One direction perpendicular to the X-axis direction is taken as a Z-axis direction. A direction perpendicular to the X-axis direction and the Z-axis direction is defined as a Y-axis direction.

The third electrodes 53 include first electrodes portions 53a. The position (the third position) of the first electrode portion 53a in the first direction D1 is between the position (the first position) of the first electrode 51 in the first direction D1 and the position (the second position) of the second electrode 52 in the first direction D1. For example, the third electrode 53 is between the first electrode 51 and the second electrode 52 in the first direction D1.

The semiconductor member 10M includes the first semiconductor region 10, the second semiconductor region 20, the first compound region 30, and the intermediate compound region 25.

The first semiconductor region 10 includes Alₓ₁Ga₁₋ₓ₁N (0≤x1<1). The composition ratio x1 may be, for example, not less than 0 and not more than 0.1. The first semiconductor region 10 includes, for example, GaN.

The first semiconductor region 10 includes a first partial region 11, a second partial region 12, a third partial region 13, a fourth partial region 14, and a fifth partial region 15. The direction from the first partial region 11 toward the first electrode 51 is aligned with the second direction D2 crossing the first direction D1. The second direction D2 is, for example, the Z-axis direction.

The direction from the second partial region 12 toward the second electrodes 52 is aligned with the second direction D2. The direction from the third partial region 13 toward the first electrode portion 53a is aligned with the second direction D2. The region overlapping the first electrode 51 in the second direction D2 corresponds to the first partial region 11. The region overlapping the second electrode 52 in the second direction D2 corresponds to the second partial region 12. The region overlapping the first electrode portion 53a in the second direction D2 corresponds to the third partial region 13.

The position (the fourth partial region position) of the fourth partial region 14 in the first direction D1 is between the position (the first partial region position) of the first partial region 11 in the first direction D1 and the position (the third partial region position) of the third partial region 13 in the first direction D1. The position (the fifth partial region position) of the fifth partial region 15 in the first direction D1 is between the third partial region position and the position (the second partial region position) of the second partial region 12 in the first direction D1. The boundaries between the plurality of partial regions may be clear or unclear.

The second conductive region 20 includes Alₓ₂Ga₁₋ₓ₂N (0<x2<1, x1<x2). The composition ratio x2 may be not less than 0.15 and not more than 0.45. The second semiconductor region 20 includes AlGaN.

The second semiconductor region 20 includes a first semiconductor portion 21 and a second semiconductor portion 22. The direction from the fourth partial region 14 toward the first semiconductor portion 21 is aligned with the second direction D2. The direction from the fifth partial region 15 toward the second semiconductor portion 22 is aligned with the second direction D2. At least a portion of the first electrode portion 53a is between the first semiconductor portion 21 and the second semiconductor portion 22 in the first direction D1.

The first compound region 30 includes Alₓ₃Ga₁₋ₓ₃N (0<x3≤1, x2<x3). The composition ratio x3 may be, for example, not less than 0.8 and not more than 1. The first compound region 30 includes, for example, AlN.

The first compound region 30 includes a first region 31, a second region 32, and a third region 33. The first region 31 is between the first semiconductor portion 21 and the first electrode portion 53a in the first direction D1. The second region 32 is between the first electrode portion 53a and the second semiconductor portion 22 in the first direction D1. The third region 33 is between the third partial region 13 and the first electrode portion 53a in the second direction D2.

The intermediate compound region 25 includes a first intermediate compound portion 25a. The first intermediate compound portion 25a is between the first electrode portion 53a and the second region 32 in the first direction D1.

The first insulating member 41 includes a first insulating region 41a, a second insulating region 41b, and a third insulating region 41c. The first insulating region 41a is between the first region 31 and the first electrode portion 53a in the first direction D1. The second insulating region 41b is between the first electrode portion 53a and the first intermediate compound portion 25a in the first direction D1. The third insulating region 41c is between the third region 33 and the first electrode portion 53a in the second direction D2. The third region 33 contacts the third partial region 13 and the third insulating region 41c.

The intermediate compound region 25 includes at least one selected from the group consisting of the first material, the second material, and the third material. The first material includes Alₓ₄Ga₁₋ₓ₄N (0≤x4<1, x4<x3). The second material includes In_{y1}Al_{y2}Ga_{1-y1-y2}N (0<y1≤1, 0≤y2<1, y1+y2≤1). The third material includes ZnO. The composition ratio x4 may be lower than the composition ratio x2.

The current that flows between the first electrode 51 and the second electrode 52 can be controlled by the potential of the third electrode 53. The potential of the third electrode 53 may be a potential with reference to the potential of the first electrode 51. The first electrode 51 functions as, for example, a source electrode. The second electrode 52 functions as, for example, a drain electrode. The third electrode 53 functions as, for example, a gate electrode. The semiconductor device 110 is a transistor.

The first semiconductor region 10 includes a portion opposing the second semiconductor region 20. A carrier region is formed in this portion. The carrier region is, for example, a Two-Dimensional Electron Gas. The semiconductor device 110 is, for example, a high electron mobility transistor (HEMT).

As described above, the first electrode portion 53a is between the first semiconductor portion 21 and the second semiconductor portion 22. The third electrode 53 is, for example, a recess gate. A high threshold voltage is easily obtained.

As described above, the semiconductor member 10M includes the first intermediate compound portion 25a. Thereby, a higher threshold voltage is obtained. In the embodiment, a high threshold voltage is obtained stably. According to the embodiment, a semiconductor device can be provided in which the characteristics can be improved.

At least a portion of the intermediate compound region 25 includes a crystal. At least a portion of the first intermediate compound portion 25a includes a crystal. The intermediate compound region 25 (the first intermediate compound portion 25a) has polarization. A high threshold voltage is stably obtained.

For example, the intermediate compound region 25 includes the first material. In this case, the composition ratio x4 may be 0 or more and 0.6 or less. The composition ratio x4 may be not less than 0 and not more than 0.3. The composition ratio x4 may be not less than 0 and not more than 0.2. The first material includes, for example, at least one selected from the group consisting of GaN and AlGaN.

For example, the intermediate compound region 25 includes the second material. For example, the second material includes InGaN or InAlGaN.

As shown in FIG. 1, the third region 33 contacts the third partial region 13 and the third insulating region 41c. The intermediate compound region 25 is not provided in the region corresponding to the third region 33. Thereby, a low on-resistance can be maintained. The intermediate compound region 25 is provided only on the side surface portion of the first electrode portion 53a. A high threshold voltage and a low on-resistance are obtained.

In the example, the first region 31 contacts the first semiconductor portion 21. For example, the first intermediate compound portion 25a contacts the second insulating region 41b and the second region 32. The second region 32 may contact the second semiconductor portion 22.

As shown in FIG. 1, the first intermediate compound portion 25a includes a first intermediate compound surface 25af opposing the second region 32. A first intermediate compound portion thickness t25 of the first intermediate compound portion 25a along a direction crossing the first intermediate compound surface 25af may be not less than 1 nm and not more than 50 nm. A high threshold voltage is stably obtained.

As shown in FIG. 1, the fourth partial region 14 includes a first surface F1 opposing the first semiconductor portion 21. The first semiconductor portion 21 includes a second surface F2 opposing the first region 31. The angle between the first surface F1 and the second surface F2 is defined as an angle θ. In the embodiment, the angle θ may be not less than 60 degrees and not more than 90 degrees. The angle θ may be less than 90 degrees. A high threshold voltage is easily obtained stably.

As shown in FIG. 1, the thickness of the first semiconductor portion 21 along the second direction D2 is defined as a first semiconductor portion thickness t21. The thickness of the fourth partial region 14 along the second direction D2 is defined as a fourth partial region thickness t14. The first semiconductor portion thickness t21 is smaller than the fourth partial region thickness t14. Stable characteristics are easily obtained.

For example, the first semiconductor portion thickness t21 may be equal to or greater than 15 nm and equal to or less than 45 nm. In one example, the first semiconductor portion thickness t21 is about 30 nm. For example, the fourth partial region thickness t14 may be not less than 400 nm and not more than 5 μm.

As shown in FIG. 1, the first insulating member 41 may include a fourth insulating region 41d and a fifth insulating region 41e. The first compound region 30 may further include a fourth region 34 and a fifth region 35. The fourth region 34 is between the first semiconductor portion 21 and the fourth insulating region 41d in the second direction D2. The fifth region 35 is between the second semiconductor portion 22 and the fifth insulating region 41e in the second direction D2.

As shown in FIG. 1, the semiconductor device 110 may further include a second insulating member 42. The second insulating member 42 includes a first insulating portion 42a and a second insulating portion 42b. The first insulating portion 42a is between the first semiconductor portion 21 and the fourth region 34 in the second direction D2. The second insulating portion 42b is between the second semiconductor portion 22 and the fifth region 35 in the second direction D2.

The second insulating member 42 may include silicon and nitrogen. The first insulating member 41 may include at least one first element selected from the group consisting of oxygen and nitrogen, and at least one second element selected from the group consisting of silicon and aluminum. For example, the first insulating member 41 may include silicon oxide.

For example, the first electrode 51 is electrically connected to the first semiconductor portion 21. The second electrode 52 is electrically connected to the second semiconductor portion 22. For example, the first electrode 51 is electrically connected to the first partial region 11. The second electrode 52 is electrically connected to the second partial region 12.

In the embodiment, the first semiconductor region 10 may not include a p-type impurity. Or, the concentration of the p-type impurity in the first semiconductor region 10 is less than 1×10¹⁷cm⁻³. Thereby, high crystallinity is obtained. For example, high mobility is obtained. A low on-resistance is obtained. The p-type impurity includes, for example, at least one selected from the group consisting of Mg, Zn, and Be.

In the embodiment, the thickness of the first compound region 30 may be not less than the 2 nm and not more than the 5 nm. The thickness of the first compound region 30 may be the thickness of the first region 31 along the second direction D2.

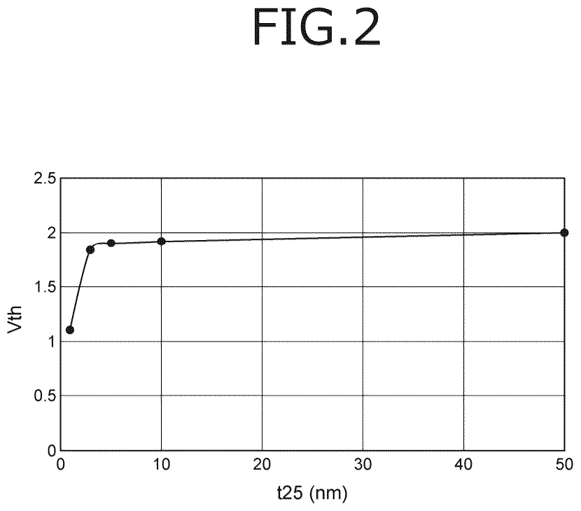

FIG. 2 is a graph illustrating characteristics of the semiconductor device according to the first embodiment. The horizontal axis of FIG. 2 is the first intermediate compound portion thickness t25. The vertical axis is the threshold voltage Vth. As shown in FIG. 2, a high threshold voltage Vth is obtained in the case where the first intermediate compound portion thickness t25 is not less than 1 nm. When the first intermediate compound portion thickness t25 is equal to or greater than 3 nm, a high threshold voltage Vth is stably obtained.

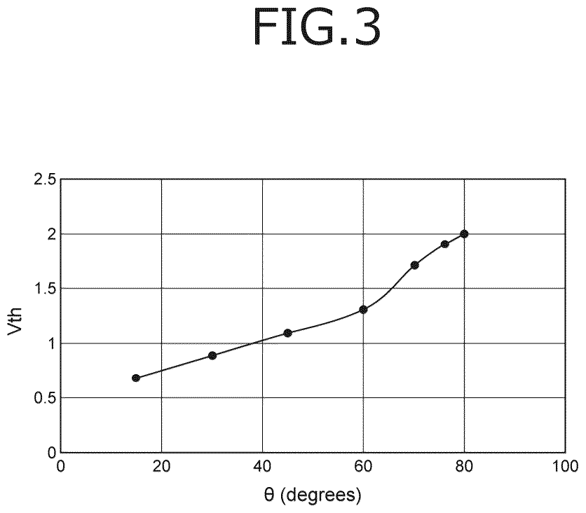

FIG. 3 is a graph illustrating characteristics of the semiconductor device according to the first embodiment. The horizontal axis of FIG. 3 is the angle θ. The vertical axis is the threshold voltage Vth. As shown in FIG. 3, the threshold voltage Vth increases as the angle θ increases. For example, a sufficiently high threshold voltage Vth is obtained when the angle θ is 60 degrees or more.

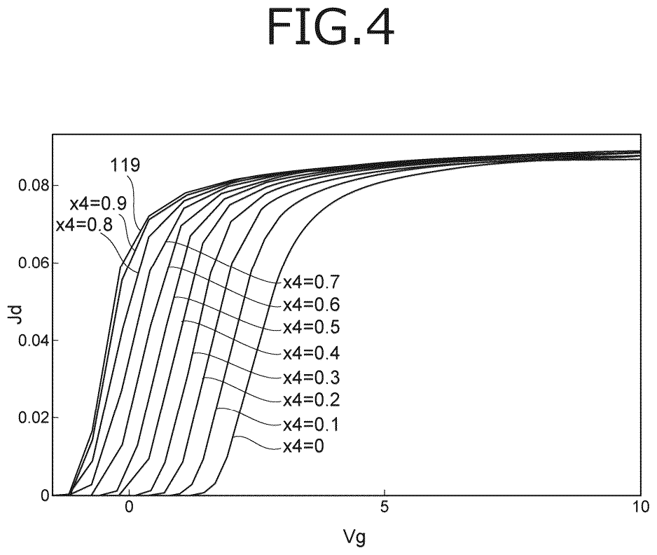

FIG. 4 is a graph illustrating characteristics of the semiconductor device according to the first embodiment. The horizontal axis of FIG. 4 is the gate voltage Vg. The vertical axis is the drain current density Jd. FIG. 4 illustrates the characteristics of the case where the intermediate compound region 25 includes the first material (Alₓ₄Ga₁₋ₓ₄N (0≤x4<1, x4<x3)) and the characteristics of the semiconductor device 119 of a first reference example. The intermediate compound region 25 (the first intermediate compound portion 25a) is not provided in the semiconductor device 119. As shown in FIG. 4, by providing the intermediate compound region 25, a higher threshold voltage is obtained than in the semiconductor device 119. The threshold voltage Vth increases as the composition ratio x4 decreases. For example, the composition ratio x4 may be 0.6 or less. The composition ratio x4 may be 0.4 or less.

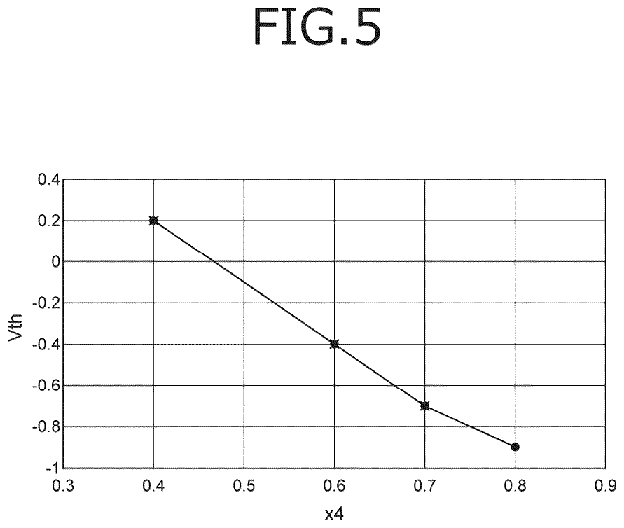

FIG. 5 is a graph illustrating characteristics of the semiconductor device according to the first embodiment. In FIG. 5, the intermediate compound region 25 includes the first material (Alₓ₄Ga₁₋ₓ₄N (0≤x4<1, x4<x3)). The horizontal axis of FIG. 4 is the composition ratio x4. The vertical axis is the threshold voltage Vth. As shown in FIG. 4, the threshold voltage Vth increases as the composition ratio x4 decreases. For example, the composition ratio x4 may be 0.6 or less. The composition ratio x4 may be 0.4 or less.

The first electrodes 51, the second electrodes 52, and the third electrodes 53 may extend along the third direction D3. The third direction D3 intersects a plane including the first direction D1 and the second direction D2. The third direction D3 may be, for example, the Y-axis direction.

In one example, a trench is formed in a structure including the first semiconductor region 10 and the second semiconductor region 20 and the first compound region 30 is formed inside the trench. The intermediate compound region 25 (the first intermediate compound portion 25a) is obtained by forming a film that is used to form the intermediate compound region 25 on the first compound region 30 and removing a portion of the film. Subsequently, the first insulating member 41 and the third electrode 53 are formed. Thereby, the structure illustrated in FIG. 1 is obtained.

In another example, a film that is used to form the intermediate compound region 25 is formed on a portion of the first compound region 30 and the intermediate compound region 25 (the first intermediate compound portion 25a) may be obtained from the film.

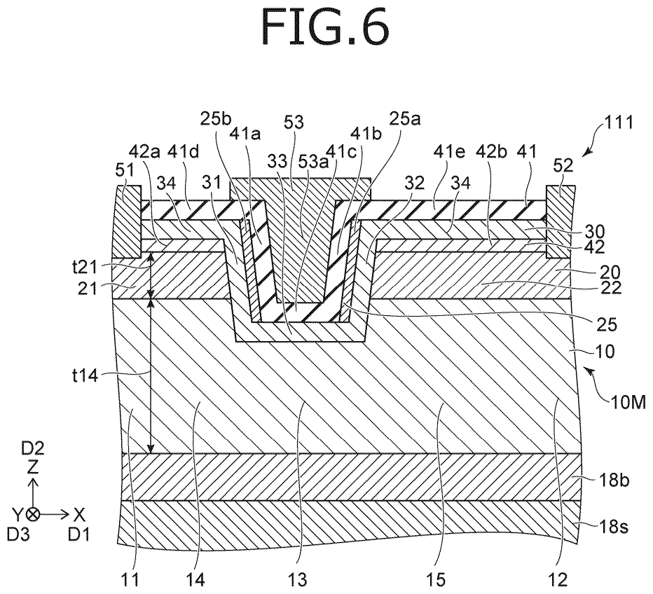

FIG. 6 is a schematic cross sectional view illustrating a semiconductor device according to the first embodiment. As shown in FIG. 6, in the semiconductor device 111 according to the embodiment, the intermediate compound region 25 further includes a second intermediate compound portion 25b. The configuration of the semiconductor device 111, excluding this, may be similar to that of the semiconductor device 110.

Thus, the intermediate compound region 25 may include the second intermediate compound portion 25b in addition to the first intermediate compound portion 25a. The second intermediate compound portion 25b is between the first region 31 and the first insulating region 41a in the first direction D1. A high threshold voltage is obtained in the semiconductor device 111 as well.

In the semiconductor device 111 as well, the third region 33 contacts the third partial region 13 and the third insulating region 41c. For example, the second intermediate compound portion 25b contacts the first region 31 and the first insulating region 41a. The first region 31 may contact the first semiconductor portion 21. The first intermediate compound portion 25a may contact the second insulating region 41b and the second region 32.

In the embodiment, the information relating to the shape of the semiconductor region, etc., is obtained by, for example, electron microscope observation, etc. Information on the composition and the element concentration in the semiconductor region is obtained by, for example, energy dispersive X-ray spectroscopy (EDX), secondary ion mass spectrometry (SIMS), or the like. The information on the composition of the semiconductor region may be obtained by, for example, reciprocal space mapping.

Hereinafter, the invention of the embodiment will be described below.

<1>

A semiconductor device comprising:
a first electrode,
a second electrode, a direction from the first electrode toward the second electrode being aligned with a first direction,
a third electrode including a first electrode portion, a third electrode position in the first direction of the first electrode portion being between a first electrode position of the first electrode in the first direction and a second electrode position of the second electrode in the first direction,
a semiconductor member,
a first insulating member, wherein
the semiconductor member includes
a first semiconductor region including Alₓ₁Ga₁₋ₓ₁N (0≤x1<1), the first semiconductor region including a first partial region, a second partial region, a third partial region, a fourth partial region, and a fifth partial region, a direction from the first partial region toward the first electrode being along a second direction crossing the first direction, a direction from the second partial region toward the second electrode being along the second direction, a direction from the third partial region toward the first electrode portion being along the second direction, a fourth partial region position of the fourth partial region in the first direction being between a first partial region position of the first partial region in the first direction and a third partial region position of the third partial region in the first direction, and a fifth partial region position of the fifth partial region in the first direction being between the third partial region position and a second partial region position of the second partial region in the first direction,
a second semiconductor region including a Alₓ₂Ga₁₋ₓ₂N (0<x2<1, x1<x2), the second semiconductor region including a first semiconductor portion and a second semiconductor portion, a direction from the fourth partial region toward the first semiconductor portion being aligned with the second direction, a direction from the fifth partial region toward the second semiconductor portion being aligned with the second direction, at least a portion of the first electrode portion being between the first semiconductor portion and the second semiconductor portion in the first direction,
a first compound region including Alₓ₃Ga₁₋ₓ₃N (0<x3≤1, x2<x3), the first compound region including a first region, a second region, and a third region, the first region being between the first semiconductor portion and the first electrode portion in the first direction, the second region being between the first electrode portion and the second semiconductor portion in the first direction, the third region being between the third partial region and the first electrode portion in the second direction, and
an intermediate compound region including a first intermediate compound portion, the first intermediate compound portion being between the first electrode portion and the second region in the first direction, wherein
the first insulating member includes a first insulating region, a second insulating region, and a third insulating region,
the first insulating region is between the first region and the first electrode portion in the first direction,
the second insulating region is between the first electrode portion and the first intermediate compound portion in the first direction,
the third insulating region is between the third region and the first electrode portion in the second direction,
the third region contacts the third partial region and the third insulating region,
the intermediate compound region includes at least one selected from the group consisting of a first material, a second material, and a third material, wherein
the first material includes Alₓ₄Ga₁₋ₓ₄N (0≤x4<1, x4<x3),
the second material includes In_{y1}Al_{y2}Ga_{1-y1-y2}N (0<y1≤1, 0≤y2<1, y1+y2≤1), and
the third material includes ZnO.
   <2>

The semiconductor device according to <1>, wherein
at least a part of the intermediate compound region includes a crystal.
   <3>

The semiconductor device according to <1> or <2>, wherein
the intermediate compound region includes the first material, and
the x4 is 0 or more and 0.6 or less.
   <4>

The semiconductor device according to <1> or <2>, wherein
the intermediate compound region includes the second material, wherein
the second material includes InGaN or InAlGaN.
   <5>

The semiconductor device according to any one of <1> to <4>, wherein
the first region is in contact with the first partial region and the first insulating region.
   <6>

The semiconductor device according to any one of <1> to <4>, wherein
the intermediate compound region further includes a second intermediate compound portion, wherein
the second intermediate compound portion is between the first region and the first insulating region in the first direction.
   <7>

The semiconductor device according to <6>, wherein
the second intermediate compound portion contacts the first region and the first insulating region.
   <8>

The semiconductor device according to <7>, wherein
the first region is in contact with the first semiconductor portion.
   <9>

The semiconductor device according to any one of <1> to <8>, wherein
the first intermediate compound portion is in contact with the second insulating region and the second region.
   <10>

The semiconductor device according to <9>, wherein
the second region is in contact with the second semiconductor portion.
   <11>

The semiconductor device according to any one of <1> to <10>, wherein
the first intermediate compound portion includes a first intermediate compound surface opposing the second region and a first intermediate compound portion thickness of the first intermediate compound portion along a direction crossing the first intermediate compound surface is not less than 1 nm and not more than 50 nm.
   <12>

The semiconductor device according to any one of <1> to <11>, wherein
the fourth partial region includes a first surface opposing the first semiconductor portion,
the first semiconductor portion includes a second surface opposing the first region, and
an angle between the first surface and the second surface is not less than 60 degrees and not more than 90 degrees.
   <13>

The semiconductor device according to <12>, wherein
the angle is less than 90 degrees.
   <14>

The semiconductor device according to any one of <1> to <13>, wherein
the first semiconductor region does not include a p-type impurity or has a concentration of the p-type impurity in the first semiconductor region is less than 1×10¹⁷ cm⁻³.
   <15>

The semiconductor device according to <14>, wherein
the p-type impurity includes at least one selected from the group consisting of Mg, Zn, and Be.
   <16>

The semiconductor device according to any one of <1> to <15>, wherein
a first semiconductor portion thickness of the first semiconductor portion along the second direction is thinner than a fourth partial region thickness of the fourth partial region along the second direction.

### <17>

The semiconductor device according to <16>, wherein
the first semiconductor portion thickness is equal to or larger than 15 nm and equal to or smaller than 45 nm,
the fourth partial region thickness is equal to or greater than 400 nm and equal to or less than 5 μm.
   <18>

The semiconductor device according to any one of <1> to <17>, wherein
the first insulating member including a fourth insulating region and a fifth insulating region,
the first compound region further includes a fourth region and a fifth region, wherein
the fourth region is between the first semiconductor portion and the fourth insulating region in the second direction, and
the fifth region is between the second semiconductor portion and the fifth insulating region in the second direction.
   <19>

The semiconductor device according to <18>, further comprising:
a second insulating member including a first insulating portion and a second insulating portion, wherein
the first insulating portion is between the first semiconductor portion and the fourth region in the second direction,
the second insulating portion is between the second semiconductor portion and the fifth region in the second direction, and
the second insulating member includes silicon and nitrogen.
   <20>

The semiconductor device according to any one of <1> to <19>, wherein
the first electrode is electrically connected to the first semiconductor portion, and
the second electrode is electrically connected to the second semiconductor portion.

According to the embodiment, a semiconductor device is provided in which the characteristics can be improved.

In the specification of the present application, the “state of being electrically connected” includes a state in which a plurality of conductors are physically in contact with each other and a current flows between the plurality of conductors. The “state of being electrically connected” includes a state in which another conductor is inserted between a plurality of conductors and a current flows between the plurality of conductors.

The embodiments of the present invention have been described above with reference to specific examples. However, the present invention is not limited to these specific examples. For example, one skilled in the art may similarly practice the invention by appropriately selecting specific configurations of components included in semiconductor devices such as electrodes, semiconductor members, semiconductor regions, intermediate compound regions, insulating members, etc., from known art; and such practice is included in the scope of the invention to the extent that similar effects can be obtained.

In addition, combinations of any two or more elements of the specific examples within a technically possible range are also included in the scope of the present invention as long as the gist of the present invention is included.

Moreover, all semiconductor devices practicable by an appropriate design modification by one skilled in the art based on the semiconductor devices described above as embodiments of the invention also are within the scope of the invention to the extent that the spirit of the invention is included.

In addition, within the scope of the idea of the present invention, those skilled in the art can conceive various changes and modifications, and it is understood that those changes and modifications also belong to the scope of the present invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. These embodiments and modifications thereof are included in the scope and gist of the invention, and are included in the invention described in the claims and the equivalent scope thereof.

What is claimed is:

1. A semiconductor device comprising:
a first electrode,
a second electrode, a direction from the first electrode toward the second electrode being aligned with a first direction,
a third electrode including a first electrode portion, a third electrode position in the first direction of the first electrode portion being between a first electrode position of the first electrode in the first direction and a second electrode position of the second electrode in the first direction,
a semiconductor member,
a first insulating member, wherein
the semiconductor member includes
a first semiconductor region including Alₓ₁Ga₁₋ₓ₁N (0≤x1<1), the first semiconductor region including a first partial region, a second partial region, a third partial region, a fourth partial region, and a fifth partial region, a direction from the first partial region toward the first electrode being along a second direction crossing the first direction, a direction from the second partial region toward the second electrode being along the second direction, a direction from the third partial region toward the first electrode portion being along the second direction, a fourth partial region position of the fourth partial region in the first direction being between a first partial region position of the first partial region in the first direction and a third partial region position of the third partial region in the first direction, and a fifth partial region position of the fifth partial region in the first direction being between the third partial region position and a second partial region position of the second partial region in the first direction,
a second semiconductor region including a Alₓ₂Ga₁₋ₓ₂N (0<x2<1, x1<x2), the second semiconductor region including a first semiconductor portion and a second semiconductor portion, a direction from the fourth partial region toward the first semiconductor portion being aligned with the second direction, a direction from the fifth partial region toward the second semiconductor portion being aligned with the second direction, at least a portion of the first electrode portion being between the first semiconductor portion and the second semiconductor portion in the first direction,
a first compound region including Alₓ₃Ga₁₋ₓ₃N (0<x3≤1, x2<x3), the first compound region including a first region, a second region, and a third region, the first region being between the first semiconductor portion and the first electrode portion in the first direction, the second region being between the first electrode portion and the second semiconductor portion in the first direction, the third region being between the third partial region and the first electrode portion in the second direction, and
an intermediate compound region including a first intermediate compound portion, the first intermediate compound portion being between the first electrode portion and the second region in the first direction, wherein
the first insulating member includes a first insulating region, a second insulating region, and a third insulating region,
the first insulating region is between the first region and the first electrode portion in the first direction,
the second insulating region is between the first electrode portion and the first intermediate compound portion in the first direction,
the third insulating region is between the third region and the first electrode portion in the second direction,
the third region contacts the third partial region and the third insulating region,
the intermediate compound region includes at least one selected from the group consisting of a first material, a second material, and a third material, wherein
the first material includes Alₓ₄Ga₁₋ₓ₄N (0≤x4<1, x4<x3),
the second material includes In_{y1}Al_{y2}Ga_{1-y1-y2}N (0<y1≤1, 0≤y2<1, y1+y2≤1), and
the third material includes ZnO.

2. The semiconductor device according to claim 1, wherein
at least a part of the intermediate compound region includes a crystal.

3. The semiconductor device according to claim 1, wherein
the intermediate compound region includes the first material, and
the x₄ is 0 or more and 0.6 or less.

4. The semiconductor device according to claim 1, wherein
the intermediate compound region includes the second material, wherein
the second material includes InGaN or InAlGaN.

5. The semiconductor device according to claim 1, wherein
the first region is in contact with the first partial region and the first insulating region.

6. The semiconductor device according to claim 1, wherein
the intermediate compound region further includes a second intermediate compound portion, wherein
the second intermediate compound portion is between the first region and the first insulating region in the first direction.

7. The semiconductor device according to claim 6, wherein
the second intermediate compound portion contacts the first region and the first insulating region.

8. The semiconductor device according to claim 7, wherein
the first region is in contact with the first semiconductor portion.

9. The semiconductor device according to claim 1, wherein
the first intermediate compound portion is in contact with the second insulating region and the second region.

10. The semiconductor device according to claim 9, wherein
the second region is in contact with the second semiconductor portion.

11. The semiconductor device according to claim 1, wherein
the first intermediate compound portion includes a first intermediate compound surface opposing the second region and a first intermediate compound portion thickness of the first intermediate compound portion along a direction crossing the first intermediate compound surface is not less than 1 nm and not more than 50 nm.

12. The semiconductor device according to claim 1, wherein
the fourth partial region includes a first surface opposing the first semiconductor portion,
the first semiconductor portion includes a second surface opposing the first region, and
an angle between the first surface and the second surface is not less than 60 degrees and not more than 90 degrees.

13. The semiconductor device according to claim 12, wherein the angle is less than 90 degrees.

14. The semiconductor device according to claim 1, wherein
the first semiconductor region does not include a p-type impurity or has a concentration of the p-type impurity in the first semiconductor region is less than 1×10¹⁷ cm⁻³.

15. The semiconductor device according to claim 14, wherein
the p-type impurity includes at least one selected from the group consisting of Mg, Zn, and Be.

16. The semiconductor device according to claim 1, wherein
a first semiconductor portion thickness of the first semiconductor portion along the second direction is thinner than a fourth partial region thickness of the fourth partial region along the second direction.

17. The semiconductor device according to claim 16, wherein
the first semiconductor portion thickness is equal to or larger than 15 nm and equal to or smaller than 45 nm,
the fourth partial region thickness is equal to or greater than 400 nm and equal to or less than 5 μm.

18. The semiconductor device according to claim 1, wherein
the first insulating member including a fourth insulating region and a fifth insulating region,
the first compound region further includes a fourth region and a fifth region, wherein
the fourth region is between the first semiconductor portion and the fourth insulating region in the second direction, and
the fifth region is between the second semiconductor portion and the fifth insulating region in the second direction.

19. The semiconductor device according to claim 18, further comprising:
a second insulating member including a first insulating portion and a second insulating portion, wherein
the first insulating portion is between the first semiconductor portion and the fourth region in the second direction,
the second insulating portion is between the second semiconductor portion and the fifth region in the second direction, and
the second insulating member includes silicon and nitrogen.

20. The semiconductor device according to claim 1, wherein
the first electrode is electrically connected to the first semiconductor portion, and
the second electrode is electrically connected to the second semiconductor portion.
